(19) United States
(12) Patent Application Publication
(10) Pub. No.: US 2014/0199909 A1
(43) Pub. Date: Jul. 17, 2014

(54) SILICONE-ORGANIC RESIN COMPOSITE LAMINATE AND MANUFACTURING METHOD THEREOF, AND LIGHT-EMITTING SEMICONDUCTOR APPARATUS USING THE SAME

(71) Applicant: SHIN-ETSU CHEMICAL CO., LTD., Tokyo (JP)

(72) Inventors: Shigeo YAMAGUCHI, Annaka (JP); Saiko AKAHANE, Annaka (JP); Toshio SHIOBARA, Annaka (JP)

(73) Assignee: SHIN-ETSU CHEMICAL CO., LTD., Tokyo (JP)

(21) Appl. No.: 14/140,267

(22) Filed: Dec. 24, 2013

(30) Foreign Application Priority Data
Jan. 17, 2013 (JP) 2013-006634

(51) Int. Cl. H01L 33/62

(52) U.S. Cl. CPC H01L 33/62
USPC 442/233; 156/60

(57) ABSTRACT

The invention provides a silicone-organic resin composite laminate comprises a laminate in which an organic resin layer containing an inorganic fiber cloth into which a thermosetting organic resin has been impregnated, and a silicone resin layer containing an inorganic fiber cloth into which a curable silicone resin has been impregnated, being laminated with each one or more layers, and metal foils laminated at an uppermost surface and a lowermost surface of the laminate. There can be provided a silicone-organic resin composite laminate which has low linear expansion, good thermal dimensional stability, excellent mechanical characteristics, and excellent heat resistance and light resistance, and is suitable as a mounting substrate for an LED which corresponds to increase in luminance of the LED mounted substrate.

### BACKGROUND OF THE INVENTION

1. Field of the Invention

The present invention relates to a silicone-organic resin composite laminate and a manufacturing method thereof, and a light-emitting semiconductor apparatus using the laminate.

2. Description of the Related Art

As a mounting substrate for an LED (Light Emitting Diode), a material in which an epoxy resin has been impregnated into a glass fiber woven fabric has widely been used. However, there is a problem that the epoxy resin is degraded by the effects of lead free solder, heat generation of parts, and light. Also, for a mounting substrate for an LED which is required to have heat resistance, ceramics such as alumina, aluminum nitride, have been used, but the cost thereof is high and mass-production of a large sized substrate is difficultly.

Thus, it has been investigated to use a laminated substrate of a silicone resin which is excellent in characteristics such as light resistance, heat resistance, and has been used for various uses as a mounting substrate for an LED. However, the conventional silicone laminated substrate has been produced by using a condensed varnish or an addition varnish so that the manufacturing method is complicated, and, there is a problem that an adhesive force is weak for adhering it to the surface of a metal foil such as a copper foil. Further, the silicone substrate has a larger expansion coefficient as compared with those of the conventional organic substrates, so that the problem generated when it is placed under severe conditions such as temperature cycles after mounting a device such as an LED on the silicone substrate, a gold wire is broken, and so on.

The silicone laminated substrate involving the above-mentioned problems or the ceramics substrate which is high cost has a possibility that they become difficult to correspond as a substrate for the general lighting usage or the display usage in the future. Thus, it has been required to develop a mounting substrate for an LED (white printed wiring substrate) which does not discolor under the high temperature heat-loaded environment nor lowering in reflectance, is usable for a large scale substrate, has thermal dimensional stability, and is reduced the cost.

In such a situation, in Patent Document 1, it has been proposed a ceramic composite copper clad laminate in which a ceramic sprayed layer is formed on one surface of the copper foil as a composite copper clad laminate, this is heat press molded with a glass fiber woven fabric prepreg to integrate them to obtain a product having a low thermal expansion coefficient, excellent dimensional stability as compared with that of the conventional copper clad laminate, and significantly improving drilling workability which is a defect of the ceramic composite copper clad laminate. However, it is extremely difficult to obtain a uniform sprayed film with a wide range when the spraying treatment is performed at a high temperature to 1083° C. which is a melting point of copper since the copper foil is as thin as 18 μm to 70 μm.

Also, in Patent Document 2, it has been proposed a printed wiring substrate material for mounting an LED which comprises a thermoplastic resin having high heat resistance, a polyorganosiloxane and a metal layer, which has high heat resistance, high reflectance at the visible light region, and lowering in reflectance under high temperature heat-loaded environment being a little. However, the thermoplastic resin is poor in thermal dimensional stability, and there remains a problem of adhesion with the polyorganosiloxane.

### PRIOR ART REFERENCES

### Patent Documents

[Patent Document 1] Japanese Patent No. 2806030

[Patent Document 2] Japanese Patent Publication Laid-Open No. 2012-116003

### SUMMARY OF THE INVENTION

The present invention has been accomplished in view of such problems, and an object thereof is to provide a silicone-organic resin composite laminate which has low linear expansion, has good thermal dimensional stability, excellent in mechanical characteristics, and has excellent heat resistance and light resistance, and suitable for an LED mounted substrate which corresponds to high illumination of the LED.

To solve the above-mentioned problems, the present invention is to provide;

a silicone-organic resin composite laminate comprising a laminate in which an organic resin layer containing an inorganic fiber cloth into which a thermosetting organic resin has been impregnated, and a silicone resin layer containing an inorganic fiber cloth into which a curable silicone resin has been impregnated, being laminated with each one or more layers, and metal foils laminated at an uppermost surface and a lowermost surface of the laminate.

When such a composite laminate is used, it becomes a silicone-organic resin composite laminate having a low linear expansion, good thermal dimensional stability, and having an organic resin layer excellent in mechanical characteristics and a silicone resin layer having excellent heat resistance and light resistance, and it can be suitably used as a mounting substrate for an LED which can correspond to increase in luminance of the LED.

Among these, it is preferred that the laminate has a three-layered structure in which the organic resin layer is made an intermediate layer, and the silicone resin layers are laminated at the upper surface and the lower surface of the organic resin layer, and a glass transition temperature of the organic resin layer is higher than that of the silicone resin layer.

By having such a laminated structure, the silicone resin layer having excellent in heat resistance and light resistance is provided at the surface portion, and the thermosetting resin layer comprising an epoxy resin having a high glass transition temperature, a low linear expansion and excellent mechanical strength, etc., is provided at the center portion, so that it can be used more suitably as a mounting substrate for an LED.

Also, a material having a linear expansion coefficient in the longitudinal direction of the organic resin layer after curing measured by a TMA method of 70 ppm/° C. or less is preferably used.

If such an organic resin layer is used, the laminate has excellent thermal dimensional stability, and delaminating at the interface of the organic resin layer and the silicone resin layer can be suppressed.

Further, a material having a water absorption rate of the organic resin layer after curing of 0.13% by mass or less is preferably used.

When such an organic resin laminate is used, it is possible to prevent from rapidly expansion due to humidity at the time of reflow in the state where the laminate absorbs humidity, and delaminating at the interface of the organic resin layer and the silicone resin layer can be suppressed.

Also, the present invention is to provide a method for manufacturing a silicone-organic resin composite laminate which comprises the steps of laminating an organic resin layer containing an inorganic fiber cloth into which a thermosetting organic resin has been impregnated, and a silicone resin prepreg containing an inorganic fiber cloth into which a curable silicone resin has been impregnated each one or more layers, and curing by heating under pressure molding.

Moreover, the present invention is to provide a method for manufacturing a silicone-organic resin composite laminate which comprises the steps of laminating an organic resin layer containing an inorganic fiber cloth into which a thermosetting organic resin has been impregnated, and a silicone resin layer containing an inorganic fiber cloth into which a curable silicone resin has been impregnated each one or more layers by adhering these using an adhesive, and curing the laminate by heating under pressure molding.

The silicone-organic resin composite laminate of the present invention can be produced by the above method.

Further, the present invention is to provide a light-emitting semiconductor apparatus produced by using the above-mentioned silicone-organic resin composite laminate.

The silicone-organic resin composite laminate of the present invention is excellent in heat resistance and light resistance, and an expansion coefficient is a little and thermal dimensional stability is also good, so that it can be suitably used as a mounting substrate for a light-emitting semiconductor apparatus such as an LED or a mounting substrate for a semiconductor apparatus and power module which are operational at high temperature such as a high voltage, large current.

The silicone-organic resin composite laminate of the present invention has a low linear expansion and good thermal dimensional stability, excellent mechanical characteristics, and has excellent heat resistance and light resistance. When such a composite laminate is used, it can be suitably used as a mounting substrate for an LED which can correspond to increase in luminance of the LED.

### DETAILED DESCRIPTION OF THE PREFERRED EMBODIMENTS

In the following, the present invention is explained in more detail.

The silicone-organic resin composite laminate of the present invention comprises a laminate in which an organic resin layer containing an inorganic fiber cloth into which a thermosetting organic resin has been impregnated, and a silicone resin layer containing an inorganic fiber cloth into which a curable silicone resin has been impregnated, being laminated with each one or more layers, and metal foils laminated at an uppermost surface and a lowermost surface of the laminate.

### (Organic Resin Layer)

The thermosetting organic resin to be contained in the organic resin layer to be used in the present invention is preferably those having a linear expansion coefficient of the thermosetting organic resin after curing is smaller than that of the silicone resin after curing, specifically mentioned a resin such as an epoxy resin, a BT resin, a phenol resin, an acrylic resin, an epoxy-modified silicone resin, a silicone-modified phenol resin and preferably an epoxy resin or a BT resin in the points of characteristics such as thermal dimensional stability, mechanical characteristics.

Also, the inorganic fiber cloth to be contained in the organic resin layer may be mentioned woven fabric comprising the following fibers.

As an example thereof, there may be used any material depending on the characteristics of the product, including an inorganic fiber such as carbon fiber, glass fiber, quartz glass fiber, metal fiber, silicon carbide fiber, titanium carbide fiber, boron fiber, alumina fiber and the like. Further, in combination of the above-mentioned fibers, an organic fiber such as an aromatic polyamide fiber, a polyimide fiber, a polyamideimide fiber may be used. Among the above-mentioned fibers, preferred fiber may be mentioned glass fiber, quartz fiber, carbon fiber and above all, glass fiber and quartz glass fiber are a more preferred material in the viewpoint of high insulating property.

As a form of these inorganic fiber cloths, it is not particularly limited so long as it can form a laminated material. As an example thereof including state material such as a roving a sheet, cloth, nonwoven fabric, and further a chopped strand mat in which long fiber filaments are arranged to a predetermined direction,. Also, a mass of the inorganic fiber cloth is preferably 20 to 450 g/m², more preferably 25 to 210 g/m².

Further, to lower the expansion coefficient as stated below, inorganic filler may be added to the thermosetting organic resin. The inorganic filler to be added may be any material so long as it is well-known inorganic filler, and may be mentioned, for example, reinforcing inorganic filler such as silica (fused silica precipitated silica, fumed silica, and the like), alumina, aluminum nitride; and non-reinforcing inorganic filler such as calcium carbonate, calcium silicate, ferric oxide, carbon black, etc. These inorganic filler may be used a single kind alone or two or more kinds in combination. By adding such inorganic filler, a linear expansion coefficient of the silicone-organic resin composite laminate of the present invention can be lowered and strength of the laminate can be improved.

Among these inorganic filler, fused silica, crystalline silica, alumina, and the like, are suitably used. A shape of these filler is preferably spherical ones since it can be highly filled, and the average particle size is preferably 10 μm or less, more preferably 3 μm or less, further preferably 1 μm or less. In particular, when it is used as a laminated substrate for an LED, silica, etc., having a particle size of ½ or less to the thickness of the substrate is preferably used since no inconvenience is generated that the light of the LED is transmitted into the substrate to lower the luminance.

An amount of the above-mentioned inorganic filler to be added is preferably in the range of 1,000 parts by mass or less (0 to 1,000 parts by mass), more preferably 10 to 900 parts by mass, particularly preferably in the range of 50 to 800 parts by mass based on 100 parts by mass of the thermosetting organic resin in the viewpoints of linear expansion coefficient and strength of the silicone-organic composite laminated substrate to be obtained.

Also, a white pigment can be blended to the thermosetting organic resin to improve optical reflectance of the laminate. As the white pigment, the well-known white pigments which have conventionally been used in general may be used without any limitation, and preferably used are titanium dioxide, zinc oxide or a combination thereof. As these white pigments, in general, those having an average particle diameter of preferably 0.05 to 1 μm, more preferably 0.1 to 0.5 μm, further preferably 0.1 to 0.3 μm or so can be used. Incidentally, the average particle diameter can be obtained, for example, as a single particle diameter by an electron microscope method. The white pigments may be used a single kind alone or two or more kinds in combination.

A blending amount of the white pigment is preferably in the range of 0.1 to 300 parts by mass, more preferably 1 to 300 parts by mass, particularly preferably 10 to 300 parts by mass, above all, preferably in the range of 30 to 300 parts by mass based on 100 parts by mass of the organic resin in the viewpoint of optical reflectance of the silicone-organic composite laminated substrate to be obtained.

The organic resin layer of the silicone-organic resin composite laminate of the present invention contains a material in which the thermosetting organic resin is impregnated into the inorganic fiber cloth. More specifically, there may be exemplified by a semi-cured state prepreg in which the thermosetting organic resin is impregnated into the inorganic fiber cloth, or a material in which the prepreg is made a cured state by heating under pressure.

The prepreg in which the thermosetting organic resin has been impregnated into the inorganic fiber cloth can be obtained by dissolving or dispersing the above-mentioned thermosetting organic resin composition is solvent and immersing an inorganic fiber cloth therein, and then, the solvent is removed by evaporating from the inorganic fiber cloth.

The solvent to be used for preparing the above-mentioned prepreg is not particularly limited so long as it can dissolve or disperse the above-mentioned thermosetting organic resin composition, and, can be evaporated at a temperature at which the thermosetting organic resin can be maintained at an uncured or semi-cured state, and may be mentioned, for example, solvent having a boiling point of 50 to 200° C., preferably 60 to 150° C. Specific examples of such solvent may be mentioned hydrocarbon series non-polar solvent such as toluene, xylene, hexane, heptane; esters, ethers, and the like. An amount of the solvent to be used is not particularly limited so long as it can dissolve or disperse the above-mentioned thermosetting organic resin, and the obtained solution or dispersion can be impregnated into the inorganic fiber cloth, and is preferably 10 to 200 parts by mass, more preferably 20 to 100 parts by mass based on 100 parts by mass of the above-mentioned resin.

The solution or dispersion of the above-mentioned thermosetting organic resin is used, for example, by impregnating the solution or dispersion into an inorganic fiber cloth such as a glass cloth and the solvent is removed in a drying furnace preferably at 50 to 150° C., more preferably at 60 to 120° C. to obtain a prepreg.

The thus prepared organic resin layer preferably has a linear expansion coefficient after curing of 70 ppm/° C. or less, more preferably 20 to 60 ppm/° C. If the linear expansion coefficient is 70 ppm/° C. or less, the product has excellent thermal dimensional stability, and delaminating at the interface between the organic resin layer and the silicone resin layer can be suppressed. Further, the silicone-organic resin composite laminate using such an organic resin layer is less deformed by heat, so that it can be suitably used as a mounting substrate for a semiconductor apparatus and power module which are operational at high temperature.

Also, the above-mentioned organic resin layer is preferably a water absorption rate after curing of 0.13% or less, more preferably 0.08% or less. Incidentally, in the present invention, the terms “water absorption rate” mean the value measured by JIS C 6481, 5.14. The organic resin layer having such characteristics is used, for example, as an intermediate layer of the three-layered structure, it is preferred since, even when soldering such as IR reflow is carried out under hygroscopic state, the characteristics as an insulating substrate is never lost by delaminating between the interface of the organic resin laminate and the silicone resin laminate due to inconveniences such as abrupt expansion which generate disconnection or leakage between wiring.

Also, the above-mentioned organic resin layer is, in particular, when it is used as an intermediate layer of the three-layered structure, preferably that having higher glass transition temperature than that of the silicone resin layer mentioned below. If the glass transition temperature is high, deformation by heat difficultly occurs whereby delaminating at the interface with the silicone resin layer can be prevented, so that it can be suitably used as a mounting substrate for a semiconductor apparatus and power module which are operational at high temperature.

### (Silicone Resin Layer)

In the curable silicone resin contained in the silicone resin layer to be used in the present invention, the curing mechanism is not particularly limited. As an example thereof, there are mentioned curing by condensation reaction, curing by utilizing an addition reaction by hydrosilylation, curing by radical reaction using a peroxide, and the like, curing by utilizing a radical polymerization reaction or a cation polymerization reaction by electron beam irradiation and these curing mechanisms may be used alone or two or more in combination. Above all, it is preferred to use a thermosetting silicone resin utilizing an addition reaction by hydrosilylation in the viewpoints of easiness in handling, thermal stability of the cured resin, etc.

Also, the inorganic fiber cloth contained in the silicone resin layer may be exemplified by the same materials as those contained in the organic resin layer.

Further, in the present invention, inorganic filler may be added to the curable silicone resin. The inorganic filler to be added may be exemplified by the same as those used in the thermosetting organic resin. Thus, by adding the inorganic filler, a linear expansion coefficient of the silicone resin layer can be lowered.

Also, a white pigment may be blended into the curable silicone resin. The white pigment may be exemplified by those the same as the thermosetting organic resin. Thus, by blending the white pigment to the curable silicone resin, optical reflectance of the laminate can be further improved.

The silicone resin layer of the silicone-organic resin composite laminate of the present invention contains a material in which the curable silicone resin is impregnated into the inorganic fiber cloth. More specifically, there may be exemplified by an uncured or semi-cured state prepreg in which the curable silicone resin is impregnated into the inorganic fiber cloth, or a material in which the prepreg is made a cured state by heating under pressure.

The prepreg in which the curable silicone resin is impregnated into the inorganic fiber cloth can be obtained by impregnating the above-mentioned curable silicone resin composition into the inorganic fiber cloth in the state of dissolving or dispersing in the solvent, then, the solvent is removed by evaporation from the inorganic fiber cloth. The solvent to be used at this time may be mentioned those which are the same as used for preparing the prepreg comprising the inorganic fiber cloth into which the thermosetting organic resin has been impregnated.

The silicone resin layer is thus prepared, and, for example, the organic resin layer is made an intermediate layer, and the silicone resins are laminated at the upper surface and the lower surface thereof to form a three-layered structure, whereby a laminate while having excellent thermal dimensional stability and mechanical characteristics of the organic resin layer, and also excellent in heat resistance, and light resistance such as discoloration resistance and tracking resistance can be obtained.

### (Manufacturing Method of Silicone-Organic Resin Composite Laminate)

The above-mentioned organic resin layer and the silicone resin layer are laminated with a number of the sheets corresponding to the thickness of the laminate, and cured by heating under pressure molding to produce the laminate. Further, metal foils are laminated to the laminate, and, for example, the thus laminated material is heated under pressure in the range of a pressure of 5 to 50 MPa and a temperature of 70 to 180° C. using a vacuum press device, etc., to produce a metal clad laminate. The metal foil to be used here is not particularly limited, and a copper foil is preferably used electrically and economically.

In the composite laminate in which laminates containing different resins are composited like the silicone-organic resin composite laminate of the present invention, there is a problem that it is generally warped. Therefore, in the present invention, metal foils are laminated at the uppermost surface and the undermost surface of the laminate. Also, in the laminate, it is desired to design so that the top and bottom may become symmetric and produce the same.

For example, when a composite laminate in which the laminate is a two-layered structure is to be produced, the organic resin prepreg or the laminate cured the same, and the silicone resin prepreg are laminated, and further the copper foils are laminated at the uppermost surface and the undermost surface thereof and curing the material by heating under pressure molding whereby a copper clad composite substrate with a two-layered structure can be produced.

Further, in the case of a composite laminate in which the laminate is a three-layered structure, silicone resin prepregs are laminated to the upper and the bottom surfaces of the organic resin prepreg or the laminate cured the same, and further the copper foils are laminated at the uppermost surface and the undermost surface thereof and curing the material by heating under pressure molding whereby a copper clad composite substrate with a three-layered structure can be produced.

In either of the two-layered structure or the three-layered structure, when a material in which the silicone resin prepreg has been cured is used, they may be laminated by using an adhesive comprising a resin such as a silicone resin or an epoxy resin.

Further, in the present invention, the composite laminate is not limited to the two-layered structure or the three-layered structure, and according to the present invention, the organic resin prepreg or a cured product thereof, and the silicone resin prepreg or a cured product thereof may be composited three or more layers in total.

The silicone-organic resin composite laminate thus obtained has a low linear expansion, good thermal dimensional stability, excellent mechanical characteristics, and excellent heat resistance and light resistance.

Also, it is preferred that an average reflectance at the wavelength of 400 to 800 nm of the material in which the metal foil is delaminated and removed to expose the silicone resin layer is 85% or more, and a lowering rate of a reflectance at the wavelength of 470 nm after heat treatment at 260° C. for 30 minutes is 5% or less.

Further, a printed wiring board can be obtained by processing the silicone-organic resin composite laminate by the generally used method such as a subtract method and a perforating method and can be made a mounting substrate for a light-emitting semiconductor apparatus.

The silicone-organic resin composite laminate of the present invention is excellent in heat resistance and light resistance, and an expansion coefficient thereof is also small so that it can be suitably used as a mounting substrate for a light-emitting semiconductor apparatus such as an LED or a mounting substrate for a semiconductor apparatus and power module which are operational at high temperature such as a high voltage, large current.

### EXAMPLES

In the following, the present invention is specifically explained by referring to Tests and Examples, but the present invention is not limited by the following Examples. Incidentally, the term “part(s)” herein means “part(s) by mass”.

### (Manufacture of Organic Resin Layer)

### Test 1

An epoxy resin varnish comprising 600 parts of spherical fused silica (trade name: ADMAFINE SO-E1, available from Admatechs Co., Ltd.) having an average particle size of 0.25 μm, 62.5 parts of ortho-cresol novolac epoxy resin (trade name: EPICLON N-665, available from DIC Corporation), 37.5 parts of novolac phenol resin (trade name: HP-850, available from Hitachi Chemical Co., Ltd.) as a curing agent, and 0.50 part of 2E4MZ (2-ethyl-4-methylimidazole) as a curing accelerator was prepared, and impregnated into glass cloth (trade name: WEA116E, available from Nitto Boseki Co., Ltd., individual weight: 104 g/m²), and dried in a heating furnace at 120° C. for 10 minutes to obtain an epoxy resin prepreg 1 having an attached amount of 60% by mass. The epoxy resin prepregs 1 were so laminated with a number of sheets that a thickness of the laminate became 0.4 mm and 1.2 mm, copper foils (thickness: 35 μm) were provided at the both surfaces, and heat and pressure molding was carried out at a pressure of 4 MPa and a temperature of 180° C. for 120 minutes to obtain a laminates 1 each having a thickness of 0.4 mm and 1.2 mm.

A water absorption rate and a linear expansion coefficient of the obtained laminates 1 were measured according to the method shown below. The results are shown in Table 1.

Water Absorption Rate

A double-sided copper clad laminate having a thickness of 0.4 mm was etched, and a test piece with a 50 mm square was pre-treated in a thermostat at 50° C. for 24 hours. The test piece was then dipped in distilled water at 23° C. for 24 hours, wiped with a dried clean cloth and a mass thereof was measured. The water absorption rate was obtained from the masses before and after water absorption by the following formula.

Water absorption rate (%)=(Mass after water absorption−Mass before water absorption)/Mass before water absorption

Linear Expansion Coefficient

A whole surface of the double-sided copper clad laminate having a thickness of 1.2 mm was etched, a test piece having a size of 2 mm×2 mm was cut out, and a linear expansion coefficient in the Z direction by the TMA method was measured with a temperature raising rate of 5° C./minute.

### Tests 2 to 4

Epoxy resin prepregs 2 to 4 and laminates 2 to 4 were prepared by the same method as in Test 1 and according to the blending and conditions shown in Table 1, and a water absorption rate and a linear expansion coefficient were measured. The results are shown in Table 1.

TABLE 1

| | Test 1 | Test 2 | Test 3 | Test 4 |
|---|---|---|---|---|
| Ortho-Cresol novolac epoxy | 62.5 | 62.5 | 62.5 | 62.5 |
| resin | | | | |
| Phenol novolac | 37.5 | 37.5 | 37.5 | 37.5 |
| 2E4MZ | 0.50 | 0.50 | 0.50 | 0.50 |
| Spherical silica | 600 | 700 | 800 | 100 |
| Water absorption rate (%) | 0.08 | 0.05 | 0.03 | 0.13 |
| Linear expansion | 26.5 | 20.5 | 12.0 | 70.0 |
| coefficient (ppm/° C.) | | | | |

### (Preparation of Silicone Resin Layer)

### Test 5

An addition curable type silicone resin base composition comprising a vinyl group-containing organopolysiloxane resin, a hydrosilyl group-containing organopolysiloxane resin, a reaction retarder, and a curing catalyst was prepared. Next, 100 parts of the addition curable type silicone resin base composition mixed with 100 parts of spherical silica (trade name: ADMAFINE SO-E1, available from Admatechs Co., Ltd., average particle size: about 0.25 μm), and 10 parts of a rutile-type titanium oxide (trade name: PF-691, available from Ishihara Sangyo Kaisha Ltd., average particle diameter: about 0.21 μm) to prepare a silicone resin varnish. The silicone resin varnish was impregnated into glass cloth (trade name: WEA05E, available from Nitto Boseki Co., Ltd., individual weight: 47 g/m²), and heat treated in a dryer at 100° C. for 8 minutes to obtain a silicone resin prepreg with an attached amount of 60% by mass.

### (Manufacture of Silicone-Organic Resin Composite Laminate)

### Example 1

A varnish in which 62.5 parts by mass of ortho-cresol novolac resin (trade name: EPICLON N-665, available from DIC Corporation), 37.5 parts by mass of phenol novolac resin (trade name: HP-850, available from Hitachi Chemical Co., Ltd.), and 0.50 parts by mass of 2E4MZ (2-methyl-4-methylimidazole) had been stirred and mixed with 600 parts by mass of spherical silica (trade name: ADMAFINE SO-E1, available from Admatechs Co., Ltd., average particle size: about 0.25 μm) was impregnated into glass cloth (trade name: WEA116E, available from Nitto Boseki Co., Ltd., mass: 104 g/m²), and treated in a dryer at 120° C. for 10 minutes to obtain an epoxy resin prepreg 5. The epoxy resin prepregs 5 were so laminated with such a number of sheets that the thickness of the finally obtained laminate became 0.4 mm and 1.2 mm, each sheet of the silicone resin prepregs prepared in Test 5 was laminated on both surfaces of the laminate, and copper foils (thickness 35 μm) were further provided on the surfaces of the silicone resin prepreg and the material was heated under pressure molding at a pressure of 4 MPa, at 180° C. for 120 minutes to obtain a silicone-epoxy resin composite three-layered double-sided copper clad laminate.

The obtained double-sided copper clad laminates were evaluated by the following evaluation methods. The results are shown in Table 2.

Linear Expansion Coefficient

A whole surface of the double-sided copper clad laminate having a thickness of 1.2 mm was etched, a test piece having a size of 2 mm×2 mm was cut out, and a linear expansion coefficient in the Z direction by the TMA method was measured with a temperature raising rate of 5° C./minute.

Water Absorption Rate

A double-sided copper clad laminate having a thickness of 0.4 mm was etched, and a test piece with a 50 mm square was pre-treated in a thermostat at 50° C. for 24 hours. The test piece was then dipped in distilled water at 23° C. for 24 hours, wiped with a dried clean cloth and a mass thereof was measured. The water absorption rate was obtained from the masses before and after water absorption by the following formula.

Water absorption rate (%)=(Mass after water absorption−Mass before water absorption)/Mass before water absorption

Heat Resistance

According to JIS C 6481, the test piece was exposed to 280° C.×60 minutes in a thermostat, and the presence or absence of blister or delaminating was examined by naked eyes.

### Heat Discoloration Resistance

A double-sided copper clad laminate having a thickness of 0.4 mm was etched, and a test piece with a 50 mm square was treated at 200° C. for 5 hours and color change of the test piece from the state before the treatment was examined with naked eyes.

Thermal Shock Test

A COB mounting substrate for an LED was prepared by using the above-mentioned double-sided copper clad laminate, an LED chip was mounted on the substrate and subjected to bonding with a gold wire, and then, encapsulated by a silicone resin to produce an LED light emitting device. The LED light emitting device was subjected to the test using a thermal shock test device (Type No.: TSE-11-A, manufactured by ESPEC CORP.) under the temperature conditions of from −60° C. to 140° C. for 1000 cycles, and then, a lighting test of the LED was carried out and evaluated whether it is lighted or not.

### Example 2

In the same manner as in Example 1 except for using the epoxy resin prepreg 2 obtained in Test 2 in place of the epoxy resin prepreg 5, a silicone-epoxy resin composite three-layered double-sided copper clad laminate was obtained. The obtained laminate was evaluated in the same manner as in Example 1. The results are shown in Table 2.

### Example 3

In the same manner as in Example 1 except for using the epoxy resin prepreg 3 obtained in Test 3 in place of the epoxy resin prepreg 5, a silicone-epoxy resin composite three-layered double-sided copper clad laminate was obtained. The obtained laminate was evaluated in the same manner as in Example 1. The results are shown in Table 2.

### Example 4

In the same manner as in Example 1 except for using a commercially available epoxy resin copper clad laminate (MCL-E-679FG available from Hitachi Chemical Co., Ltd.) in which the copper foil has been removed by etching in place of the epoxy resin prepreg 5, a silicone-epoxy resin composite three-layered double-sided copper clad laminate was obtained. The obtained laminate was evaluated in the same manner as in Example 1. The results are shown in Table 2.

### Example 5

In the same manner as in Example 1 except for using the epoxy resin prepreg 4 obtained in Test 4 in place of the epoxy resin prepreg 5, a silicone-epoxy resin composite three-layered double-sided copper clad laminate was obtained. The obtained laminate was evaluated in the same manner as in Example 1. The results are shown in Table 2.

### Example 6

In the same manner as in Example 1 except for using a laminate of a commercially available BT resin copper clad laminate (CCL-HL832NS available from Mitsubishi Gas Chemical Company, Inc.) in which the copper foil has been removed by etching in place of the epoxy resin prepreg 5, a silicone-BT resin composite three-layered double-sided copper clad laminate was obtained. The obtained laminate was evaluated in the same manner as in Example 1. The results are shown in Table 2.

### Example 7

By using the copper clad laminates of Examples 1 to 6, the exposure test at 288° C.×60 minutes was performed according to the method described in IPC TM650 2.4.24.1. As a result, in Examples 1 to 6, neither delaminating nor generation of blister of the organic silicone resin layer was observed.

Also, when these laminates were subjected to the exposure test at 180° C. for 10 hours, no heat discoloration was generated.

### Comparative Example 1

The silicone prepregs shown in Test 5 were so laminated that a thickness of the finally obtained laminate became 0.4 mm and 1.2 mm, and copper foils (thickness: 35 μm) were provided on both surfaces thereof and the material was subjected to heat molding at a pressure of 4 MPa, a temperature of 180° C. for 120 minutes to obtain laminates each having a thickness of 0.4 mm and 1.2 mm. By using these laminates, a water absorption rate and a linear expansion coefficient of the laminates were measured by the method described in Example 1, and evaluations of the heat resistance, heat discoloration resistance, and thermal shock test were carried out. The results are shown in Table 2.

### Comparative Example 2

In the same manner as in Example 1 except for using a thermoplastic resin film comprising 40% by mass of a polyether ketone resin and 60% by mass of a polyether imide resin in place of the thermosetting epoxy resin laminate used in Example 4, a silicone-thermoplastic resin composite three-layered laminate was produced. By using the laminate, a water absorption rate and a linear expansion coefficient of the laminate were measured by the same method described in Example 1, and evaluations of the heat resistance, heat discoloration resistance, and thermal shock test were carried out. The results are shown in Table 2.

### Comparative Example 3

In the producing of the silicone-epoxy resin composite three-layered copper clad laminate described in Example 1, when a laminate was tried to produce by providing the copper foil on one surface of the laminate, then warpage of the laminate was generated after heating under press molding. It was judged that the evaluations thereof would be difficult in such a state, so that the evaluations as in Example 1 were not carried out.

TABLE 2

| | Example 1 | Example 2 | Example 3 | Example 4 |
|---|---|---|---|---|
| Linear | 30.0 | 23.5 | 17.5 | 22.0 |
| expansion | | | | |
| coefficient | | | | |
| (ppm/° C.) | | | | |
| Water | 0.08 | 0.05 | 0.03 | 0.08 |
| absorption | | | | |
| rate (%) | | | | |
| Heat | No blister | No blister | No blister | No blister |
| resistance | | | | |
| Heat | No color | No color | No color | No color |
| discoloration | change | change | change | change |
| resistance | | | | |
| Thermal shock | 0/10 | 0/10 | 0/10 | 0/10 |
| test | | | | |
| | | | Compara- | Compara- |
| | | | tive | tive |
| | Example 5 | Example 6 | Example 1 | Example 2 |
| Linear | 32.5 | 70.0 | 130.0 | 50.0 |
| expansion | | | | |
| coefficient | | | | |
| (ppm/° C.) | | | | |
| Water | 0.08 | 0.11 | 0.02 | 0.16 |
| absorption | | | | |
| rate (%) | | | | |
| Heat | No blister | No blister | No blister | Blister |
| resistance | | | | present |
| Heat | No color | No color | No color | No color |
| discoloration | change | change | change | change |
| resistance | | | | |
| Thermal shock | 0/10 | 0/10 | 3/10 | 10/10 |
| test | | | | |

In Examples 1 to 6, delaminating at the organic silicone resin layer, blister and heat discoloration were not generated, and LEDs using these laminate were all turn on. Also, in Comparative Example 1, the linear expansion coefficient was large so that 3 samples of the LEDs produced using the same was not turn on among 10 samples. In Comparative Example 2, blister was generated in the heat resistance test, and the LEDs produced using the same was not turn on. In Comparative Example 3, the copper foil was not adhered to the upper surface or the lower surface so that warpage was generated at the time of producing of the laminate whereby it could not be applied to the tests.

From the results as mentioned above, according to the silicone-organic resin composite laminates of the present invention, it could be clarified that they have low linear expansion and good thermal dimensional stability, excellent mechanical characteristics, and have excellent heat resistance and light resistance, so that they could be suitably used as a mounting substrate for an LED which could correspond to high illumination of the LED.

It must be stated here that the present invention is not restricted to the embodiments shown by Examples. The embodiments shown by Examples are merely examples so that any embodiments composed of substantially the same technical concept as disclosed in the claims of the present invention and expressing a similar effect are included in the technical scope of the present invention.

What is claimed is:

1. A silicone-organic resin composite laminate comprising a laminate in which an organic resin layer containing an inorganic fiber cloth into which a thermosetting organic resin has been impregnated, and a silicone resin layer containing an inorganic fiber cloth into which a curable silicone resin has been impregnated, being laminated with each one or more layers, and metal foils laminated at an uppermost surface and a lowermost surface of the laminate.

2. The silicone-organic resin composite laminate according to claim 1, wherein the laminate has a three-layered structure in which the organic resin layer is made an intermediate layer, and the silicone resin layers are laminated at the upper surface and the lower surface of the organic resin layer, and a glass transition temperature of the organic resin layer is higher than that of the silicone resin layer.

3. The silicone-organic resin composite laminate according to claim 1, wherein a linear expansion coefficient in the longitudinal direction of the organic resin layer after curing by a TMA method is 70 ppm/° C. or less.

4. The silicone-organic resin composite laminate according to claim 2, wherein a linear expansion coefficient in the longitudinal direction of the organic resin layer after curing by a TMA method is 70 ppm/° C. or less.

5. The silicone-organic resin composite laminate according to claim 1, wherein a water absorption rate of the organic resin layer after curing is 0.13% by mass or less.

6. The silicone-organic resin composite laminate according to claim 2, wherein a water absorption rate of the organic resin layer after curing is 0.13% by mass or less.

7. The silicone-organic resin composite laminate according to claim 3, wherein a water absorption rate of the organic resin layer after curing is 0.13% by mass or less.

8. The silicone-organic resin composite laminate according to claim 4, wherein a water absorption rate of the organic resin layer after curing is 0.13% by mass or less.

9. A method for manufacturing the silicone-organic resin composite laminate according to claim 1, which comprises the steps of:
laminating an organic resin layer containing an inorganic fiber cloth into which a thermosetting organic resin has been impregnated, and a silicone resin prepreg containing an inorganic fiber cloth into which a curable silicone resin has been impregnated each one or more layers, and
curing by heating under pressure molding.

10. A method for manufacturing the silicone-organic resin composite laminate according to claim 1, which comprises the steps of:
laminating an organic resin layer containing an inorganic fiber cloth into which a thermosetting organic resin has been impregnated, and a silicone resin layer containing an inorganic fiber cloth into which a curable silicone resin has been impregnated each one or more layers by adhering these using an adhesive, and
curing by heating under pressure molding.

11. A light-emitting semiconductor apparatus produced by using the silicone-organic resin composite laminate according to claim 1.
